(19) United States
(12) Patent Application Publication
(10) Pub. No.: US 2009/0277389 A1
(43) Pub. Date: Nov. 12, 2009

(54) PROCESSING APPARATUS

(75) Inventor: Akinobu Kakimoto, Yamanashi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: TOKYO ELECTRON LIMITED, Minato-ku (JP)

(21) Appl. No.: 12/296,167

(22) PCT Filed: Apr. 5, 2007
(86) PCT No.: PCT/JP2007/057666

§ 371 Date: Oct. 6, 2008

(30) Foreign Application Priority Data
Apr. 5, 2006 (JP) 2006-104731

(51) Int. Cl. C23C 16/00

(52) U.S. Cl. 118/725

(57) ABSTRACT

A processing apparatus is provided for performing a process on a target object in a processing chamber which can be vacuumized, especially for performing high-k dielectric of HfO, HfSiO, ZrO, ZrSiO, PZT, BST and the like. A film adhesion preventing layer composed of an SAM (self-assembled monolayer) is arranged on the surface of the constituent member of the processing chamber to be exposed to the processing atmosphere in the processing chamber, for instance, on the inner wall surface of the processing chamber. Thus, on the surface of the constituent member, an unnecessary film difficult to be removed by dry cleaning is prevented from being deposited, so that cleaning frequency of the processing apparatus can be remarkably reduced.

### FIELD OF THE INVENTION

The present invention relates to a processing apparatus for performing a predetermined process such as film formation or the like on a target object to be processed such as a semiconductor wafer or the like.

### BACKGROUND OF THE INVENTION

Generally, in semiconductor integrated circuit manufacturing processes, various heat treatments such as film formation, oxidation/diffusion, annealing, modification, etching and the like are repetitively performed on a semiconductor wafer as a substrate to be processed. For example, for the film formation, there is used a film forming apparatus in which a mounting table made of aluminum compound is provided in a cylindrical processing chamber made of aluminum. During the processing, the mounting table is heated by a resistance heater embedded therein, and the semiconductor wafer mounted on the mounting table is maintained at a predetermined temperature. At the same time, a predetermined processing gas, i.e., a film forming gas, is supplied from a shower head provided above the mounting table. Accordingly, a thin film such as a metal film, an insulating film or the like is formed on the wafer surface (see, e.g., Japanese Patent Laid-open Application No. JP2004-193396).

During the film formation, a required thin film is deposited on the wafer surface and, also, an unnecessary thin film is deposited on various constituent members of the processing apparatus to be exposed to the processing atmosphere, for instance, on an inner wall surface of the processing chamber and various internal structures disposed in the processing chamber (e.g., members provided near the wafer, such as a clamp ring and the like, or a shower head). The unnecessary thin film is peeled off and becomes particles, thus deteriorating a production yield of the process. Therefore, the unnecessary thin film is removed, at regular intervals (e.g., whenever 25 wafers are processed) by using a corrosive dry cleaning gas, e.g., ClF₃ or NF₃, before it is peeled off to be particles.

Meanwhile, a film which is recently suggested or a film formed by reaction by-products generated during the suggested film formation may not react with the above-described dry cleaning gas. Or, even if it reacts therewith, it may be unable or difficult to be removed by the dry cleaning gas due to a low vapor pressure of reaction products. An example of such a film is a high-dielectric thin film (high-k dielectric film) as a gate insulating film having good electrical characteristics, e.g., HfO, HfSiO, ZrO, ZrSiO, PZT, BST or the like.

Japanese Patent Laid-open Application No. JP2004-288900 discloses a method for cleaning a processing chamber in a film forming apparatus which forms a thin film difficult to be removed by dry cleaning. Here, a protection cover made of quartz is detachably attached on the surface exposed in the processing chamber, e.g., on the inner wall surface of the processing chamber. After the film formation is carried out with respect to a specified number of the wafers, the protection cover is unloaded from the processing chamber, and then the thin film adhered on the protection cover is removed by wet cleaning using a strong cleaning solution.

However, the above method is disadvantageous in that the protection cover needs to be attached and detached by opening the processing chamber to the atmosphere whenever the cleaning process is performed and, hence, the operation of the apparatus is stopped for a long period of time. As a result, a throughput decreases remarkably, and a maintenance cost increases greatly.

### SUMMARY OF THE INVENTION

In view of the above, the present invention provides a technique capable of reducing cleaning frequency remarkably by preventing an unnecessary thin film from being deposited on a surface of a member exposed to the processing atmosphere in a processing chamber.

The present invention is conceived from the conclusion obtained by the inventors that an unnecessary film can be prevented from being deposited on a surface of a member by forming on the entire surface of the member a self-assembled monolayer (SAM) used in a method for forming a selective epitaxy film such as a ZnO film or the like.

In accordance with the present invention, there is provided a processing apparatus for performing a process on a target object in an evacuable processing chamber, the processing apparatus including: a constituent member which forms the processing apparatus and is exposed to the processing atmosphere in the processing chamber; and a film adhesion preventing layer which is formed of a self-assembled monolayer (SAM) and is formed on a surface of the constituent member.

In accordance with the present invention, the deposition of the unnecessary film is suppressed by the film adhesion preventing layer formed of an SAM and, thus, the cleaning frequency is remarkably reduced. Accordingly, the throughput of the apparatus can be improved, and the maintenance cost of the apparatus can be greatly decreased.

The film adhesion preventing layer formed of the SAM can be arranged on any constituent member of the processing chamber to be exposed to the processing atmosphere. The SAM can be easily formed on silicon oxide and quartz. The film deposition prevention layer formed of the SAM can be properly arranged on a quartz constituent member. An example of the quartz constituent member is, e.g., a quartz processing chamber, a quartz wafer boat, a shower head formed of quartz pipes, a quartz lift pin or the like. However, it is not limited thereto.

Even when a constituent member is made of a material difficult to form the SAM forming the film adhesion preventing layer, an unnecessary film can be prevented from being deposited on the constituent member by providing a cover (e.g., a protective cover member) or a coating (e.g., a silicon oxide film) made of a material easy to form the SAM on the surface of the constituent member. Such a technique can be applied, e.g., when the SAM needs to be formed on the surface of the processing chamber made of metal or on the mounting table made of ceramic for mounting thereon the substrate to be processed. Moreover, the SAM can be directly formed on the metal surface by performing hydrogen termination treatment on the metal surface.

The SAM may be made of any one of OTS (octadecyltrichlorosilane), DTS (docosyltrichlorosilane) and APTS (3-aminopropyltriethoxysilane), but it is not limited thereto.

The present invention is suitable for a film forming apparatus for forming the above-described film difficult to be removed by dry cleaning, and is able to prevent an unnecessary thin film made of a reaction product or a reaction by-product from being deposited.

### BRIEF DESCRIPTION OF THE DRAWINGS

FIG. 1 shows a schematic cross sectional view of a first embodiment of a processing apparatus in accordance with the present invention;

FIG. 2 describes a schematic top view of a processing chamber of the processing apparatus of FIG. 1;

FIGS. 3A and 3B provide an explanatory view for explaining an operation of an SAM;

FIG. 4 illustrates an example of a structural formula of the SAM;

FIG. 5 offers a flow chart describing a SAM forming method;

FIG. 6 presents a schematic cross sectional view of a second embodiment of the processing apparatus in accordance with the present invention; and

FIG. 7 represents a schematic cross sectional view of a third embodiment of the processing apparatus in accordance with the present invention.

### DETAILED DESCRIPTION OF THE EMBODIMENT

Embodiments of the present invention will be described with reference to the accompanying drawings which form a part hereof.

### First Embodiment

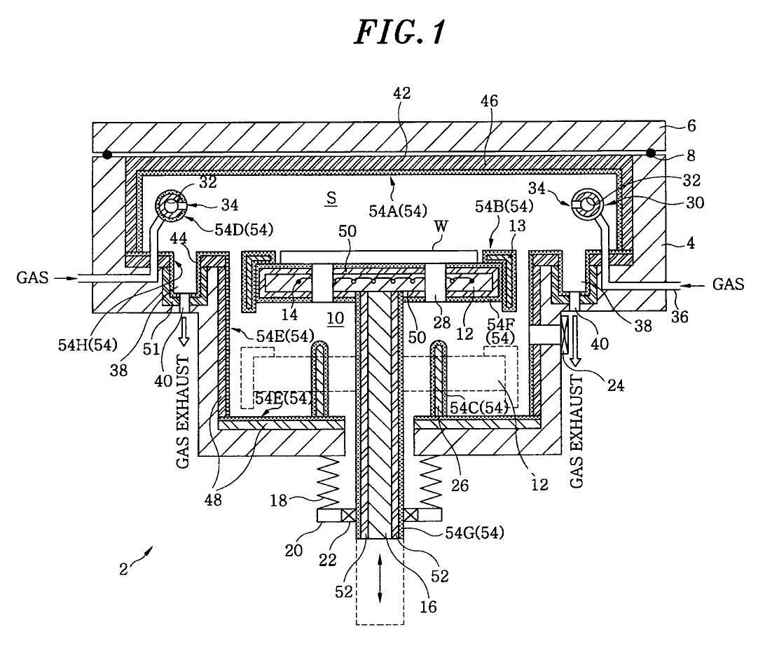

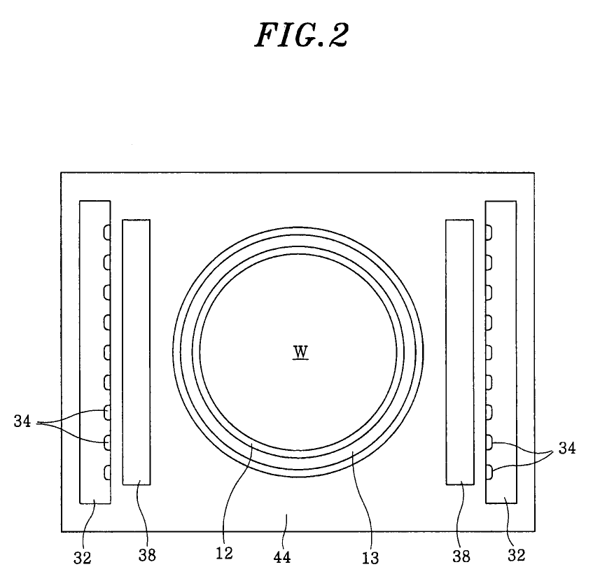

As illustrated in FIGS. 1 and 2, a single wafer processing apparatus 2 includes a processing chamber 4 made of aluminum alloy. The processing chamber 4 has an opening at a top end thereof, and a ceiling lid 6 made of aluminum alloy is airtightly and detachably attached to the opening via a sealing member 8 such as an O ring or the like. A cylindrical portion projects downward from a central portion of the processing chamber 4 in order to define a loading/unloading chamber 10 for loading/unloading a semiconductor wafer W as a substrate to be processed. A mounting table 12 made of ceramic or aluminum alloy is provided at the central portion of the processing chamber 4, and the semiconductor wafer W is mounted and held on the top surface of the mounting table 12.

In the processing chamber 4, a processing space S is formed between the ceiling member 6 and the mounting table 12 positioned as shown in FIG. 1. A heating unit, e.g., a resistance heater 14, is buried in the mounting table 12, so that the wafer W can be heated. A ring-shaped quartz guide ring 13 having an L-shaped cross section is attached around a peripheral portion of the mounting table 12.

A downwardly extending support column 16 made of, e.g., ceramic or aluminum alloy, is connected to the central portion of the backside of the mounting table 12, thereby supporting the mounting table 12. A lower portion of the support column 16 penetrates a bottom wall of the processing chamber 4, and a lower end of the support column 16 is connected to an elevation mechanism (not shown). Therefore, the mounting table 12 can move vertically together with the support column 16.

An expansible/contractible bellows 18 surrounding the peripheral portion of the support column 16 is connected to a portion where the support column 16 penetrates the bottom wall of the processing chamber 4, so that the mounting table 12 can be raised and lowered while maintaining the airtightness in the processing chamber 4. By raising and lowering the mounting table 12, the mounting table 12 can move vertically with respect to lift pins 26, which will be described later. The bellows 18 is connected to the support column 16 via a bearing 20, and the bearing 20 is provided with a magnetic fluid seal 22 in order to allow rotation of the support column 16 while maintaining the airtightness in the processing chamber 4.

Provided on the sidewall of the processing chamber that defines the loading/unloading chamber 10 is a gate valve 24 which is opened and closed when loading and unloading the wafer W. Three lift pins 26 made of quartz (only two are illustrated in FIG. 1) are extended upward from the bottom wall of the processing chamber 4 that defines the loading/unloading chamber 10. The mounting table 12 has pin holes 28 through which the lift pins 26 can pass. When the mounting table 12 is located at a lower position (indicated by the broken line in FIG. 1), the wafer W mounted on the top surface of the mounting table 12 is separated from the mounting table 12 and supported by the upper ends of the lift pins 26. In that state, the wafer W can be received by a transfer arm (not shown) loaded into the loading/unloading chamber 10 via the open gate valve 24. When the wafer W is loaded, the wafer W can be mounted on the mounting table 12 in a reverse sequence.

Provided on both sides of the processing space S are gas supply units 30 for introducing a required gas into the processing space S. To be specific, the gas supply units 30 have gas injection pipes 32 formed of quartz lines extending in a width direction of the processing space S. Each of the gas injection pipes 32 has a plurality of gas injection holes 34. The gas flows at a controlled flow rate in a gas channel 36 connected from the outside of the processing chamber 4 to the gas injection pipes 32, and is injected through the gas injection holes 34 in a horizontal direction.

Formed on both sides of the bottom wall of the processing chamber 4 that defines the processing space S are gas exhausting grooves 38 extending in the width direction of the processing space S. The gas exhausting grooves 38 communicate with gas exhaust ports 40, and the gas exhaust ports 40 are connected to a gas exhaust system having a vacuum pump (not shown) and a pressure control valve (not shown). Accordingly, the processing chamber 4 can be evacuated to vacuum.

In the processing space S, a protection cover 42 is provided along inner surfaces of the ceiling lid 6 and the processing chamber 4 that defines the processing space S. To be specific, the protection cover 42 includes a bottom plate 44 made of quartz for covering the top surface of the bottom wall of the processing chamber 4 and a lid-shaped body 46 made of quartz for covering the inner surface of the sidewall of the processing chamber and the bottom surface of the ceiling lid 6. When the processing chamber 4 is considered as an outer chamber member, the protection cover 42 can be considered as an inner chamber member. The bottom plate 44 and the lid-shaped body 46 can be detached from the processing chamber 4 by detaching the ceiling lid 6 from the processing chamber 4. Further, quartz is largely classified into fused quartz and synthetic quartz (quartz produced by a flame hydrolysis deposition), and the fused quartz is classified into a flame fused quartz and electrically fused quartz depending on a manufacturing method. As for a quartz as a material to form an SAM to be described later, it is preferable to use a high purity synthetic quartz or electrically fused quartz.

Further, a protection cover 48 made of quartz is provided on the inner wall surface, i.e., the inner surface of the sidewall and the top surface of the bottom wall, of the processing chamber 4 which faces the loading/unloading chamber 10. Furthermore, the entire surface of the mounting table 12, the entire inner surface of the gas exhaust grooves 38 and the entire surface of the support column 16 are covered by the protection covers 50, 51 and 52 made of quartz, respectively.

In the illustrated embodiment, the film adhesion preventing layers 54 having an SAM formed on a quartz surface are formed on internal structures made of quartz and the protection covers covering internal structures made of a material other than quartz. To be specific, the film adhesion preventing layers 54 (54A, 54B, 54C, 54D, 54E, 54F, 54G and 54H) are formed on the protection cover 42 (the bottom plate 44 and the lid-shaped body 46), the guide ring 13, the lift pins 26, the gas injection pipes 32, and the protection covers 48, 50, 51 and 52. Further, the above-described members are only examples, and the film adhesion preventing layer formed of an SAM may be formed on any quartz member exposed to the processing atmosphere in the processing chamber 4. A thickness of the film adhesion preventing layer formed of an SAM is preferably about 3 to 10 nm. Moreover, the film adhesion preventing layer may not be necessarily formed on the entire surface of a single member, and may be formed only on portions where an unnecessary film could be deposited.

Hereinafter, a film forming process will be described as an example of a process performed by using the processing apparatus 2. At first, in a state where the mounting table 12 is lowered, an unprocessed semiconductor wafer W is loaded into the loading/unloading chamber 10 via the open gate valve 24 by a transfer arm (not shown) capable of extending, contracting and moving vertically, and is mounted on the lift pins 26.

Next, the transfer arm is retreated from the loading/unloading chamber 10, and the gate valve 24 is closed, thereby airtightly sealing the processing chamber 4. Thereafter, the mounting table 12 is raised, and the wafer W on the lift pins 26 is mounted on the top surface of the mounting table 12. Further, the wafer W is heated to a predetermined processing temperature by the resistance heater 14 and, also, a film forming gas is supplied through the gas injection holes 34 of the gas injection pipes 32. At the same time, the processing chamber 4 is exhausted to vacuum through the gas exhausting grooves 38, and is maintained at a predetermined process pressure. While the film forming process is carried out, the wafer W is rotated by rotating the mounting table 12 and, hence, a thin film having uniform thickness is deposited on the surface of the wafer W.

During the film forming process, the film adhesion preventing layer 54 formed of an SAM prevents an unnecessary film from being deposited on the surfaces of the members exposed to the processing atmosphere. Accordingly, the cleaning frequency is remarkably reduced and, hence, it is possible to improve the throughput and decrease the maintenance cost of the apparatus considerably. The effect of preventing film adhesion can be obtained when forming a film, such as an insulating film, e.g., a SiO₂ film, a metal film, a metal nitride film, a metal oxide film or the like, which is relatively easy to be removed by a cleaning gas, e.g., ClF₃, NF₃ or the like, and also when forming a high-dielectric thin film, such as HfO, HfSiO, ZrO, ZrSiO, PZT, BST or the like, which is difficult to be removed by the cleaning gas.

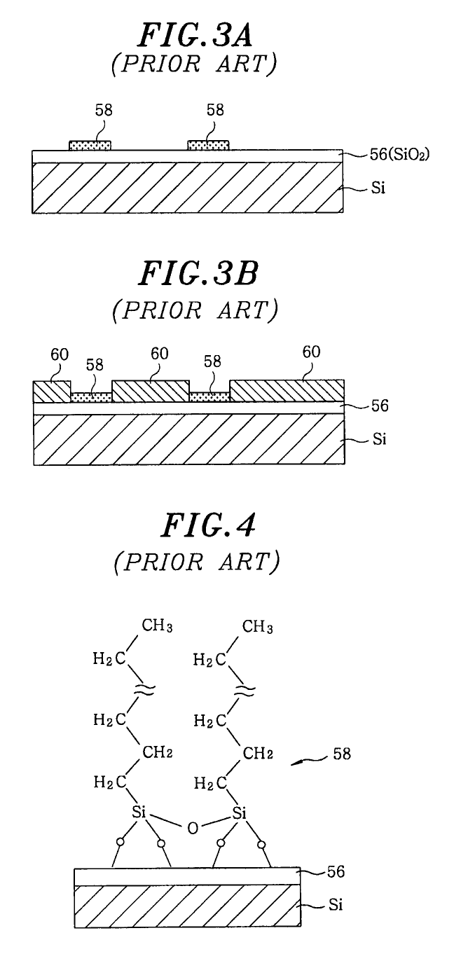

In the following, the SAM will be described with reference to FIGS. 3A, 3B and 4. The manufacturing method and the function of the SAM are described in the following four articles.

Article 1: “Selective-area atomic layer epitaxy growth of ZnO feature on soft lithography patterned substrate” Applied Physics Letters Vol. 79 pp. 1709-1711 (2001), (Yan et al.)

Article 2: “Templated Site-Selective Deposition of Titanium Dioxide on Self-Assembled Monolayers” Chemistry of Materials Letters Vol. 14 pp. 1236-1241 (2002), (Masuda et al.)

Article 3: “In Situ Time-Resolved X-ray Reflectivity Study of Self-Assembly from Solution” Langmuir pp. 5980-5983 (1998), (A. G. Richter et al.)

Article 4: “Journal of Vacuum Science and Technology B” Vol. 21 pp. 1773-1776 (2003), (Kang et al.)

Referring to Article 1, a self-assembled monolayer of a docosyltrichlorosilane (DTS-SAM) is formed on a selected region of a SiO₂ film of a silicon substrate, and an ZnO film (thickness of about 60 nm) is grown on the silicon substrate by an ALE (Atomic Layer Epitaxy) method and, hence, the ZnO film is not grown on the region where the SAM is formed, but grown on the SiO₂ film where the SAM is not formed.

Referring to Article 2, APTS (3-aminopropyltriethoxysilane)-SAM (self-assembled monolayer) is formed on a selected region of a SiO₂ film of a silicon substrate and, then, the silicon substrate is immersed in an aqueous solution of (NH₄)₂TiF₆ to which H₃BO₃ is added as an impurity remover, thereby growing a TiO₂ film. In this case as well, the TiO₂ film is not grown on the region where the SAM is formed, but grown on the SiO₂ film where the SAM is not formed.

Referring to Article 3, there is described a method for forming an octadecyltrichlorosilane self-assembled monolayer (OTS-SAM).

Referring to Article 4, an OTS-SAM is formed on a selected region of a SiO₂ film of a silicon substrate and, then, a TiO₂ film (thickness of about 60 nm) is grown on the silicon substrate by a MOCVD (Metal Organic Chemical Vapor Deposition) method. In this case as well, the TiO₂ film is not grown on the region where the SAM is formed, but grown on the SiO₂ film where the SAM is not formed.

Referring to Articles 1, 2 and 4, when an SAM 58 is partially formed on a SiO₂ film (quartz) 56 formed on a surface of a silicon substrate Si as shown in FIG. 3A, if a film forming process is performed on the silicon substrate Si, a thin film (ZnO or TiO₂) is not grown on the SAM 58 but grown on the exposed SiO₂ film (quartz) 56 as depicted in FIG. 3B. From the above, it is clear that an unnecessary film can be prevented from being deposited on a surface of a quartz member by forming an SAM on the surface of the quartz member.

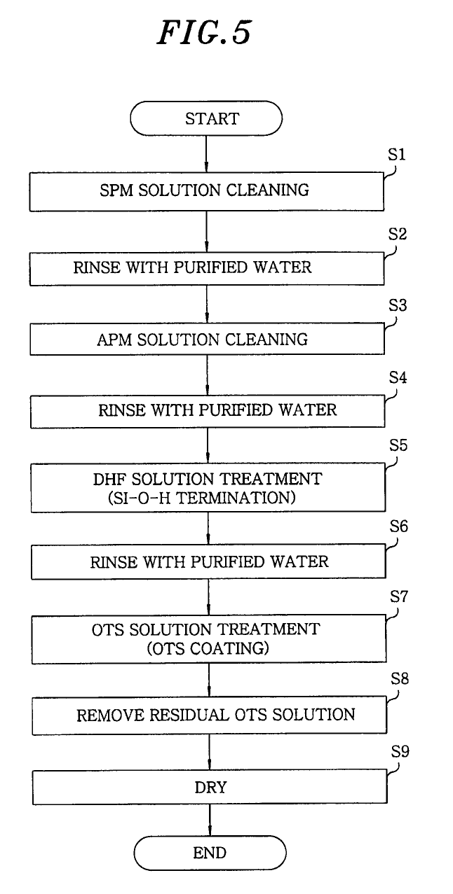

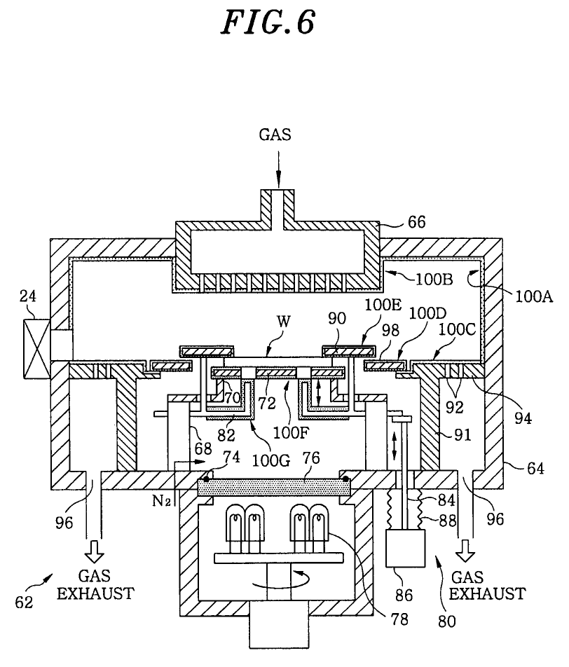

Hereinafter, an example of an SAM forming method will be described in detail with reference to FIG. 5. Here, an OTS-SAM is formed by using a method similar to the method described in Article 3. First of all, a quartz member, i.e., a target object onto which a film adhesion preventing layer needs to be formed, is immersed in an SPM solution (H₂SO₄:30% H₂O₂=70:30) for a predetermined period of time, e.g., about one hour, thus removing carbon adhered on the surface of the target object (S1).

Next, the target object is rinsed with purified water to sufficiently remove residual SPM solution (S2). Thereafter, the target object is immersed in an APM solution (NH₄OH:H₂O₂:H₂O=1:1:5) at a room temperature for a predetermined period of time, e.g., about 30 minutes, thereby removing particles adhered to the surface of the target object (S3). Then, the target object is rinsed with purified water to remove residual APM solution (S4). Next, the target object is immersed in a DHF solution (HF:H₂O=1:50) at a room temperature for a predetermined period of time, e.g., about 2 minutes, so that the molecular structure on the surface of quartz is terminated with Si—O—H bonds (S5). Thereafter, the target object is rinsed with purified water to remove residual DHF solution (S6).

Next, moisture on the surface of the target object is sufficiently removed by using dry nitrogen and, then, the target object is exposed to the dry atmosphere (the air atmosphere having a low moisture concentration). The target object is immersed in an OTS solution diluted in advance with heptane for a predetermined period of time, e.g., about 2 to 4 days, under the dry atmosphere (S7). Further, the OTS solution is made in advance by diluting OTS (99%) with heptane (Aldrich, 99%, anhydrous) under the dry atmosphere such that the concentration of the OTS becomes about 30%. Due to the immersing treatment, Cl of CH₃—[CH₂]₁₇—Si—Cl₃ of the OTS is substituted with H of Si—O—H and, accordingly, the OTS-SAM is formed on the entire surface of the target object made of quartz.

Thereafter, the OTS which is not coupled with quartz is removed from the target object by using an organic solvent such as acetone or the like (S8). The step S8 is performed to prevent particles from being generated by coupling the OTS, which is not coupled with quartz, with water when the target object is exposed to oxidation species under the ALD (Atomic Layered Deposition) process atmosphere using water. After the residual OTS solution is removed, the target object is dried (S9), and the SAM forming process is completed.

Moreover, in order to form a constituent member of which surface is covered with a protective cover member, the protective cover member on which the SAM is formed may be installed at the corresponding constituent member, or the SAM forming process may be performed on the assembled body obtained by assembling the protective cover member to the main body of the constituent member. In that case, it is preferable to form the SAM by vaporizing the protective cover member or exposing the protective cover member to a mist-shaped precursor of the SAM. Besides, the SAM forming method is not limited to the method using an OTS, and the SAM may be formed by using another precursor such as DTS, APTS or the like. Further, although the film adhesion preventing layers 54A to 54H formed of an SAM are formed on all the members facing the space in the processing chamber 4 in the apparatus of FIG. 1, the film adhesion preventing layer may be formed on some of the members.

The member on which the film adhesion preventing layer is formed in accordance with the present invention can be properly used for a film forming apparatus for performing any film forming method, e.g., a CVD (chemical vapor deposition) method, an ALD (atomic layer deposition) method, a plasma CVD method, a physical vapor deposition method, and a sputter film forming method. In a film forming apparatus for performing a plasma CVD method using a microwave, there may be used a shower head in which a top plate formed of a quartz plate for transmitting microwave is combined with quartz pipes having gas injection holes in a ring shape or in a lattice shape. Preferably, the film adhesion preventing layer formed of an SAM may be arranged on the surface of the quartz member.

Further, the member on which the film adhesion preventing layer is formed in accordance with the present invention can be used not only in a film forming apparatus but also in any processing apparatus, e.g., a plasma etching processing apparatus, an oxidation/diffusion processing apparatus, a modification processing apparatus or the like. In that case, it is possible to prevent the deposition of the by-product produced by the treatment. Moreover, the object to be processed by the processing apparatus in accordance with the present invention is not limited to a semiconductor wafer, and may be another substrate such as a glass substrate, an LCD substrate, a ceramic substrate or the like.

### Second Embodiment

In the first embodiment, the SAM is formed on the surface of the quartz member. However, a film adhesion preventing layer formed of an SAM may be formed a surface of a member made of a material other than quartz, e.g., ceramic or metal such as stainless steel, aluminum alloy or the like. Further, when the SAM needs to be formed on the metal member or the ceramic member, the following methods can be employed.

(1) The surface of the metal is subjected to hydrogen termination (terminated with H) by using active hydrogen. The hydrogen termination can be carried out by performing the plasma processing under following processing conditions.

Hydrogen flow rate: 10 to 2000 sccm

Pressure: atmospheric pressure to 1 Torr

Temperature: room temperature to 300° C.

Plasma output power: 500 to 2000 W

The plasma may be either an RF plasma or a microwave plasma.

After the hydrogen termination is carried out, the SAM can be formed on the metal surface by performing the aforementioned steps S7 to S9.

(2) A SiO₂ film is formed on the surface of the metal member or the ceramic member. As for a method for forming a SiO₂ film, there can be used any known method, e.g., a CVD method, a sputter method, a sol-gel method, a coating method or the like. After the SiO₂ film is formed, the surface of the SiO₂ film is subjected to hydrogen termination by executing the aforementioned steps S1 to S6 or by performing the plasma processing of the above method (1). Thereafter, the aforementioned steps S7 to S9 are carried out, thus forming the SAM on the metal member or the ceramic member.

FIG. 6 illustrates a processing apparatus in accordance with the second embodiment of the present invention, in which an SAM is formed on a surface of a member made of a material other than quartz. In FIG. 6, like reference numerals will be used to indicate like parts in FIG. 1, and redundant description thereof will be omitted.

A processing apparatus 62 includes a processing chamber 64 made of aluminum alloy. A shower head 66 made of aluminum alloy is provided at a ceiling portion of the processing chamber 64, so that a required gas can be supplied into the processing chamber 64. In the processing chamber 64, a mounting table 72 formed of a thin ceramic plate is supported by a plurality of support arms 70 extending from an upper end portion of a cylindrical support column 68, and a wafer W is mounted on the mounting table 72.

Installed below the mounting table 72 is a transmitting window 76 formed of a quartz plate which is airtightly attached to a bottom opening of the processing chamber 64 via a sealing member 74 such as an O-ring or the like. A plurality of rotatable heating lamps 78 as heating units are provided below the transmitting window 76. The heating lamps 78 indirectly heat the wafer W by heating the backside of the mounting table 72. Disposed below the mounting table 72 are quartz lift pins 82 forming a part of a lift pin mechanism 80. An actuator rod 84 for raising the lift pins 82 penetrates the bottom wall of the processing chamber 64. When an actuator 86 is driven, the actuator rod 84 and the lift pins 82 connected thereto are moved up and down. A bellows 88 surrounding the periphery of the actuator rod 84 maintains the airtightness in the processing chamber 64 while allowing the vertical movement of the actuator rod 84.

A ring-shaped clamp ring 90 made of ceramic is provided near the periphery of the mounting table 72 in order to clamp and fix the peripheral portion of the wafer W to the mounting table 72. The clamp ring 90 is connected to the lift pins 82 and moves vertically together with the lift pins 82. A rectifying plate 94 made of aluminum alloy and having a plurality of gas holes 92 is provided around the mounting table 72. The atmosphere in the processing chamber 64 can be exhausted to vacuum via a gas exhaust port 96 disposed below the rectifying plate 94. A ring-shaped attachment member 98 made of ceramic is provided while being supported by a cylindrical support member 91.

A film adhesion preventing layer 100A formed of an SAM is formed on an inner wall surface of the processing chamber 64. Further, film adhesion preventing layers 100B, 100C, 100D, 100E, 100F and 100G are formed on the surfaces of the shower head 66, the rectifying plate 94, the attachment member 98, the clamp ring 90, the mounting table 72 and the lift pins 82, respectively. In the second embodiment, as in the first embodiment, it is possible to prevent an unnecessary film from being deposited on surfaces of the members.

### Third Embodiment

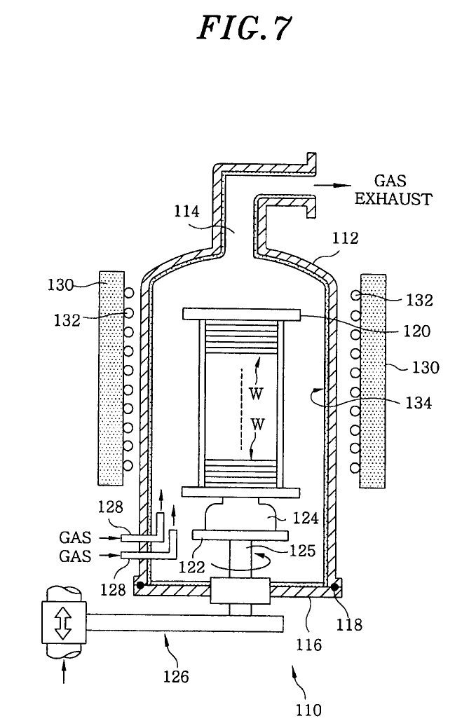

The processing apparatus in accordance with the first and the second embodiment is a single wafer processing apparatus for processing a semiconductor wafer one by one. However, it is not limited thereto, and may be a batch type processing apparatus for processing a plurality of wafers at a time. FIG. 7 depicts a batch type processing apparatus in accordance with a third embodiment of the present invention.

A batch type processing apparatus 110 includes a cylindrical processing chamber 112 made of quartz. A gas exhaust port 114 is provided at an upper end portion of the processing chamber 112. The processing chamber 112 has an opening at a lower end thereof, and the lower end opening is closed by a lid 116 made of stainless steel via a sealing member 118 such as an O-ring or the like.

Provided in the processing chamber 112 is a quartz wafer boat 120 for supporting wafers W at multiple levels. The wafer boat 120 is installed on a rotatable table 122 via a heat-insulating tube 124 made of quartz. A rotation shaft 125 extending downward from the rotatable table 122 penetrates the lid 116, and a space between the rotation shaft 125 and the lid 116 is sealed. The lid 116 is moved vertically by means of a boat elevator 126, so that the wafer boat 120 mounted on the lid 116 can be loaded into and unloaded from the processing chamber 112.

Moreover, a gas nozzle 128 made of quartz penetrates a lower sidewall of the processing chamber 112 in order to supply a required gas into the processing chamber 112. A cylindrical thermal insulator 130 and a heater 132 attached thereto are provided around the processing chamber 112 in order to heat the wafers W. In the batch type processing apparatus 110 in accordance with the third embodiment as well, film adhesion preventing layers 134 formed of an SAM are formed on the inner wall surface of the processing chamber 112 made of quartz, the surface of the wafer boat 120 made of quartz, the surface of the heat-insulating tube 124 made of quartz, the surface of the gas nozzle 128 made of quartz, the inner surface of the lid 116 made of stainless steel and the like, respectively. For simplicity of the drawing, FIG. 7 only shows the film adhesion preventing layer 134 on the inner surface of the lid 116 and the inner wall surface of the processing chamber 112. In this case as well, it is possible to prevent an unnecessary film from being deposited on surface of members as in the first and the second embodiment.

Further, although it is not described in the first to the third embodiment, a glass coating may be provided on a gas inlet line for introducing a gas into the processing chamber or an inner side of a gas outlet line for discharging the gas from the processing chamber. In this case, a film adhesion preventing layer formed of an SAM may be formed on the surface of the glass coating.

What is claimed is:

1. A processing apparatus for performing a process on a target object in an evacuable processing chamber, the processing apparatus comprising:
a constituent member which forms the processing apparatus and is exposed to the processing atmosphere in the processing chamber; and
a film adhesion preventing layer which is formed of a self-assembled monolayer (SAM) and is formed on a surface of the constituent member.

2. The processing apparatus of claim 1, wherein at least a surface of the constituent member is made of quartz, and the film adhesion preventing layer is directly formed on the surface of the quartz.

3. The processing apparatus of claim 2, wherein the constituent member is entirely made of quartz.

4. The processing apparatus of claim 1, wherein the constituent member has a main body made of a material other than quartz and a protection cover made of quartz for covering a surface of the main body, and the film adhesion preventing layer is formed on a surface of the protection cover.

5. The processing apparatus of claim 4, wherein the protection cover is detachably attached to the main body.

6. The processing apparatus of claim 1, wherein the constituent member has a main body made of a material other than quartz and a coating layer for coating a surface of the main body, and a film adhesion preventing layer is formed on a surface of the coating layer.

7. The processing apparatus of claim 6, wherein the coating layer is a SiO₂ film.

8. The processing apparatus of claim 1, wherein the constituent member is the processing chamber.

9. The processing apparatus of claim 8, wherein the processing chamber is made of quartz, and the film adhesion preventing layer is directly formed on the quartz.

10. The processing apparatus of claim 8, wherein the processing chamber is made of a material other than quartz, and the film adhesion preventing layer is formed on a surface of a protection cover made of quartz for covering an inner wall surface of the processing chamber.

11. The processing apparatus of claim 8, wherein the processing chamber is made of a material other than quartz, and the film adhesion preventing layer is formed on a SiO₂ film coated on an inner wall surface of the processing chamber.

12. The processing apparatus of claim 1, wherein the SAM is made of any one of OTS (octadecyltrichlorosilane), DTS (docosyltrichlorosilane) and APTS (3-aminopropyltriethoxysilane).

13. The processing apparatus of claim 1, wherein the process is a film forming process or a sputter process.

14. The processing apparatus of claim 1, wherein the process is a film forming process for forming any one of a high-k dielectric film, an insulating film, a metal film, a metal nitride film and a metal oxide film.
